(19) United States
(12) Patent Application Publication
(10) Pub. No.: US 2026/0039306 A1
(43) Pub. Date: Feb. 5, 2026

(54) BACKGROUND DAC ERROR CALIBRATION FOR SAR ADCS

(71) Applicant: Analog Devices, Inc., Wilmington, MA (US)

(72) Inventors: Efram Burlingame, San Diego, CA (US); Enrique Alvarez-Fontecilla, Encinitas, CA (US)

(21) Appl. No.: 18/789,225

(22) Filed: Jul. 30, 2024

(51) Int. Cl. H03M 1/06; H03M 1/10

(52) U.S. Cl. CPC H03M 1/0639; H03M 1/1047

(57) ABSTRACT

An analog-to-digital converter (ADC) includes bit trial circuitry configured to perform ADC bit trials that compare an input signal to states of weighted circuit elements, a dither digital-to-analog converter (DAC) to receive a dither sequence and apply a dither signal to the bit trial circuitry, and calibration circuitry. The calibration circuitry is configured to input a dither sequence into the ADC bit trials as dithered bit trials; determine an effect of the dither sequence on results of the dithered bit trials; and update correction factors used to adjust results of the ADC bit trials using the determined effect of the dither sequence.

### BACKGROUND

Electronic systems can include analog-to-digital (A/D) converters (ADCs). ADCs are circuits that convert analog signals to digital quantities to allow processors of electronic systems to perform signal processing functions for the systems. A successive approximation register (SAR) ADC is one type of ADC. In a SAR ADC, an analog input to be converted is sampled and held. A digital-to-analog converter (DAC) element is set to midscale and a comparator determines whether the sampled and held input is higher or lower than the DAC output and a bit result is stored in a successive approximation register. The DAC output is set based on the previous bit result and compared to the sampled and held input. The process continues until all the bit values are determined. Accuracy of an A/D conversion is susceptible to errors in the DAC element, or DAC errors. DAC errors can lead to issues such as harmonic distortion in an electronic system using a SAR ADC.

### OVERVIEW

This document relates generally to analog-to-digital converter (ADC) circuits, and in particular to improvements in the operation of successive approximation register (SAR) ADCs. An ADC example includes bit trial circuitry configured to perform ADC bit trials that compare an input signal to states of weighted circuit elements; a dither digital-to-analog converter (DAC) to receive a dither sequence and apply a dither signal to the bit trial circuitry; and calibration circuitry. The calibration circuitry is configured to input a dither sequence into the ADC bit trials as dithered bit trials; determine an effect of the dither sequence on results of the dithered bit trials; and update correction factors used to adjust results of the ADC bit trials using the determined effect of the dither sequence.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a diagram of an example of a successive approximation register analog-to-digital converter (SAR ADC).

FIG. 2 is a diagram of an example of operation of a SAR ADC.

FIGS. 3A and 3B are illustrations of effects of weighting errors in a digital-to-analog converter (DAC) elements of a SAR ADC.

FIGS. 4 and 5 are diagrams of further example models of a SAR ADC.

FIG. 6 is a graph of examples of transfer curves for ADCs.

FIG. 7 is a diagram of another example of a SAR ADC.

FIGS. 8A and 8B are graphs showing examples of transfer curves for the SAR ADC example of FIG. 7.

FIG. 9 is a graph illustrating an example of a computation useful for calibrating an ADC.

FIG. 10 shows graphs showing examples of transfer functions for different types of error in a SAR ADC.

FIG. 11 is a diagram of an example of a circuit to detect instantaneous error in operation of a SAR ADC.

FIG. 12 is a diagram of an example of a SAR ADC model and calibration circuitry.

FIG. 13 is a diagram of another example of a circuit to detect instantaneous error in operation of a SAR ADC.

FIG. 14 is a diagram of another example of a model of a SAR ADC.

FIG. 15 is a flow diagram of an example of a method to calibrate a SAR ADC.

### DETAILED DESCRIPTION

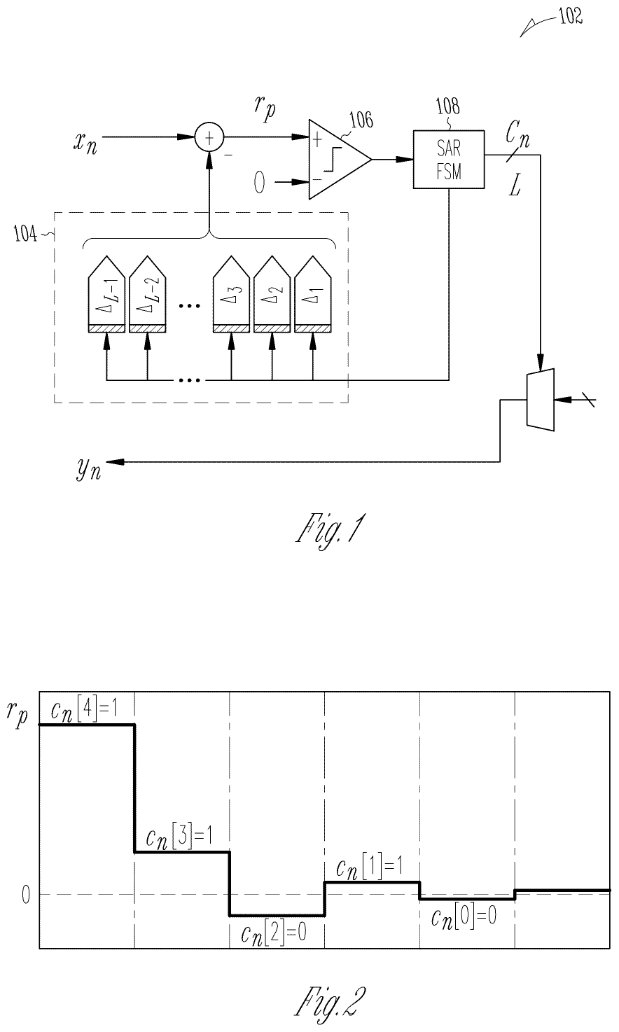

FIG. 1 is a diagram of an example of a successive approximation register analog-to-digital converter (SAR ADC). The SAR ADC 102 includes a digital-to-analog converter (DAC) 104 with L−1 DAC elements (where L is a positive integer greater than one and is the number of conversion trials of the SAR ADC), a comparator 106, and logic circuitry that can include a SAR finite state machine (SAR FSM) 108. The input xₙ is the analog input signal to be converted and yₙ is the digital ADC output. The DAC elements can be weighted DAC elements with weights (Δ_{L-1}, . . . , Δ₁).

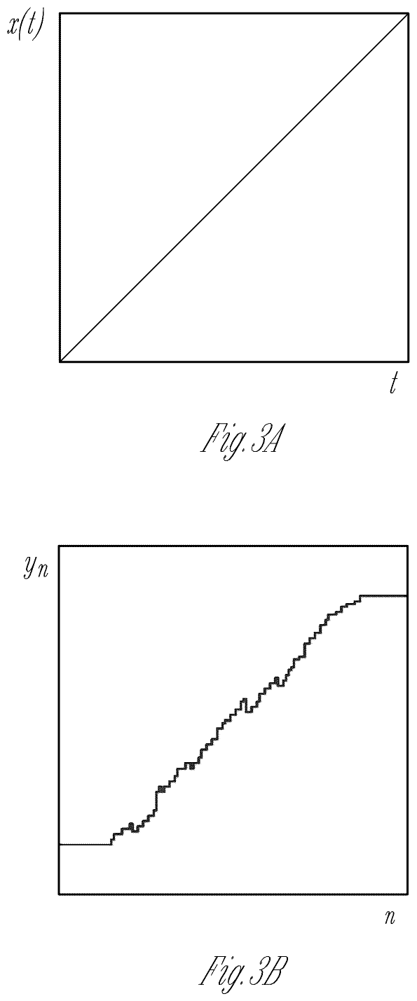

FIG. 2 is a diagram of an example of operation of a 5-bit binary-weighted SAR ADC. As part of the successive approximation routine, bit trials are performed iteratively. In a bit trial, the outputs of the weighted DAC elements are applied to the inputs of the comparator 106. Based on the output of the comparator 106, the bit of the digital value corresponding to a DAC element is assigned a logic value ‘1’ or a logic value ‘0’. Conversion then proceeds to the next trial until all bits of the digital value are determined.

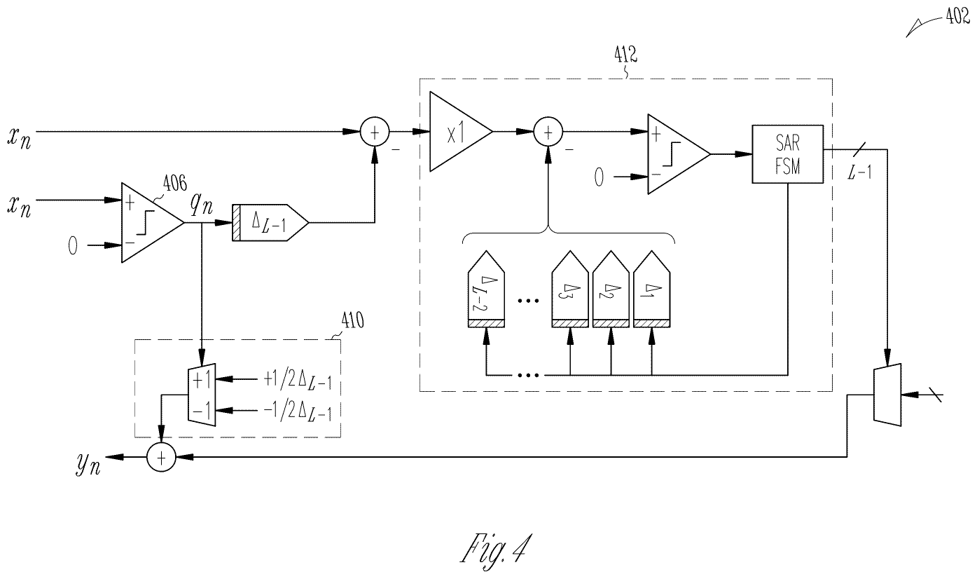

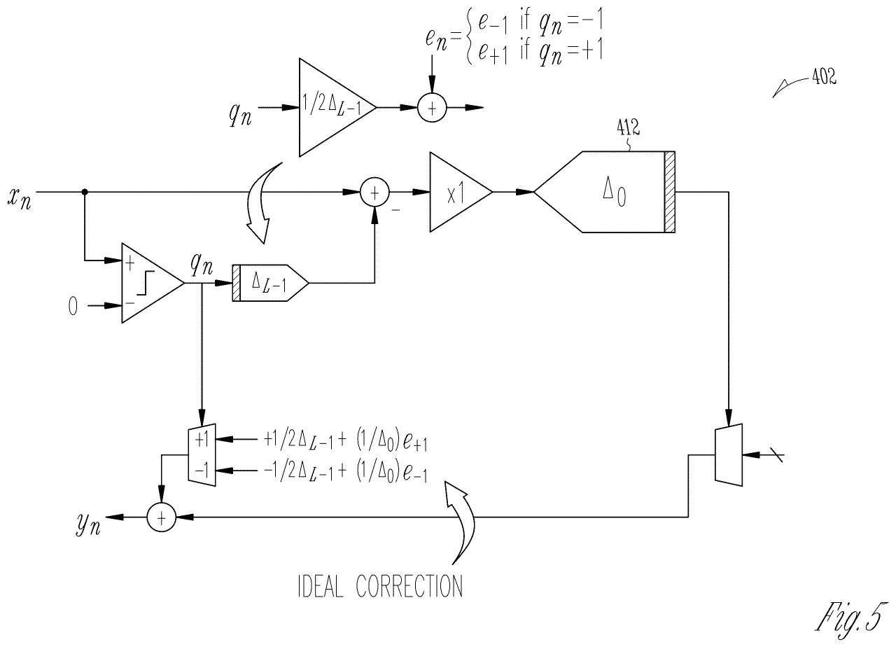

FIGS. 3A and 3B are graphs illustrating the effects of errors in the weighting of the DAC elements. For instance, in the case of capacitive DAC arrays, there may be inaccuracies in the capacitance values in the weighting of the DAC elements. FIG. 3A shows the input x(t) as an input increasing linearly, and FIG. 3B shows the problem that can occur in the output yₙ when there are errors in the weighting. The increase in the output for increasing digital values may not be linear and may cause harmonic distortion in the application. One approach to address errors in the DAC elements is to calibrate the bit trials of the ADC. The calibration changes the decision point of the bit trials to address errors in the weighting of the DAC elements used in the bit trials.

FIG. 4 is a diagram of another example of a model of a SAR ADC 402. The SAR ADC model 402 is equivalent to the SAR ADC 102 of FIG. 1 except that a portion of bit trial logic 410 is shown isolated from the rest of the SAR ADC 412. The output of the comparator 406 is interpreted as ±1 and the bit trial logic 410 adds or subtracts one half the weight of DAC element L−1 (±½Δ_{L-1}) to output yₙ according to the output of the comparator qₙ and the output of the rest of the SAR ADC 412.

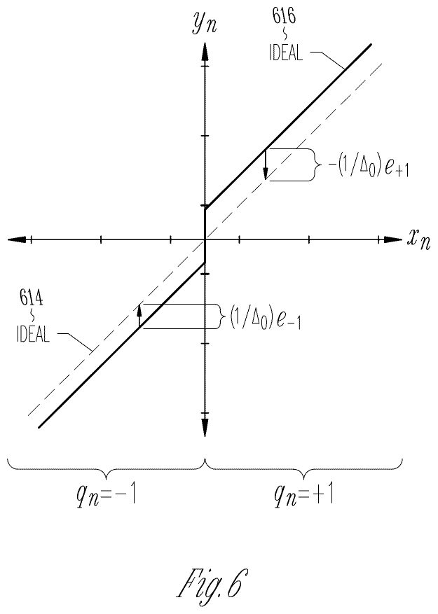

FIG. 5 is an illustration of an example of DAC element error on the SAR ADC 402. In FIG. 5 all but the most significant bit DAC element Δ_{L-1} and its associated trial logic is represented by a back-end ADC 412. In the example of FIG. 5, the DAC element Δ_{L-1} introduces an error eₙ in its bit trials due to error in its weighting. The error eₙ is e₊₁ when the output of comparator qₙ is +1, and the error eₙ is e₋₁ when the output of comparator qₙ is −1. With error eₙ, instead of adjusting the result by +½Δ_{L-1} when the output of the comparator is qₙ=+1, the result is ideally adjusted by +½Δ_{L-1}+(1/Δ₀)e₊₁ (where 1/Δ₀ is a scaling factor), and when the output of the comparator is qₙ=−1, the result is adjusted by −½Δ_{L-1}+(1/A₀)e₋₁ instead of −½Δ_{L-1}.

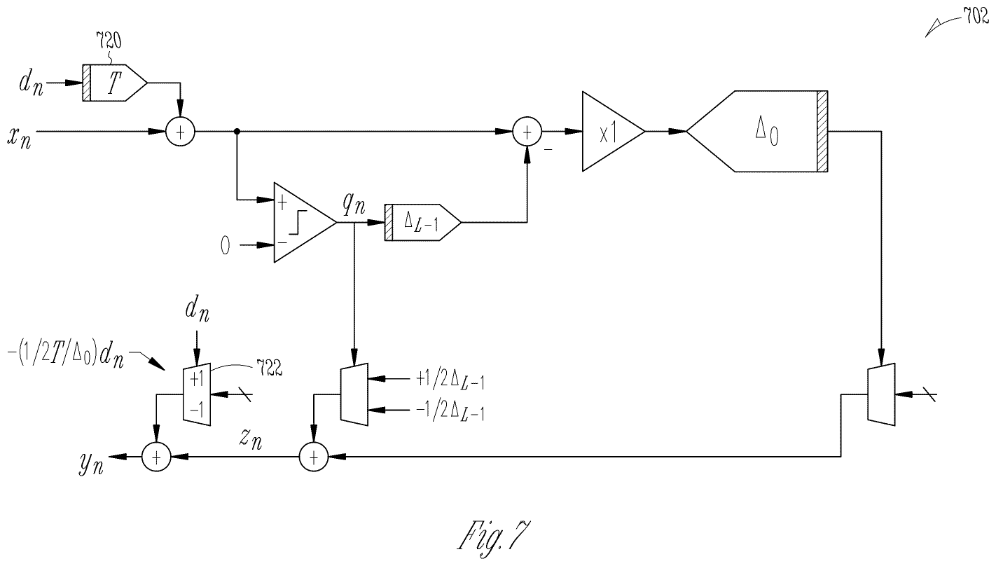

FIG. 6 is graph of a transfer curve of output yₙ vs. input xₙ showing the ideal transfer curve 614 without the error and the actual transfer curve 616 with the error eₙ. The left portion of the graph shows that adjusting the result of bit trials with +(1/Δ₀)e₋₁ when qₙ=−1 brings the result back to ideal, and the right portion of the graph shows that adjusting the result of bit trials with +(1/Δ₀)e₊₁ when qₙ=+1 brings the result back to ideal. The example in FIG. 6 shows that calibrating the bit trials of the DAC elements with a correction factor may bring the performance of the ADC closer to ideal and reduce distortion in the A/D conversions. A challenge is knowing when the error places the actual result greater than ideal or less than ideal.

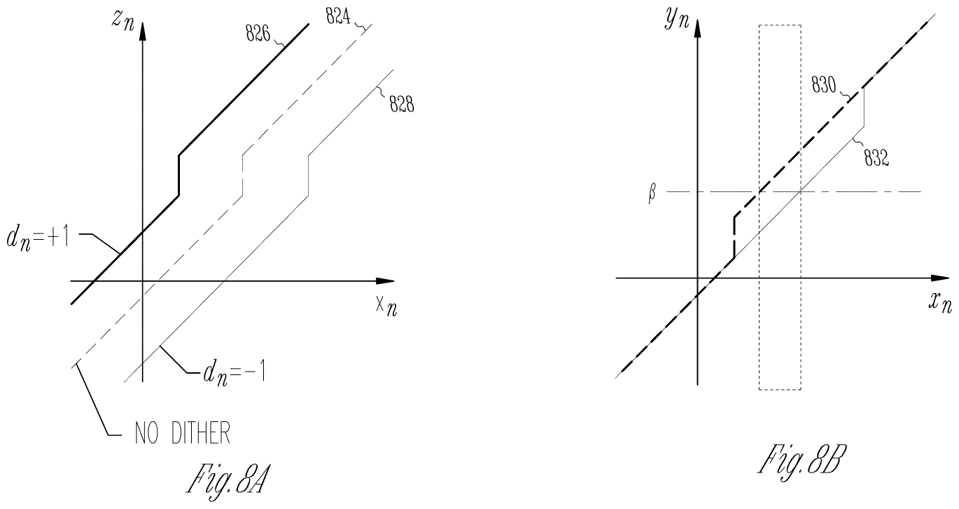

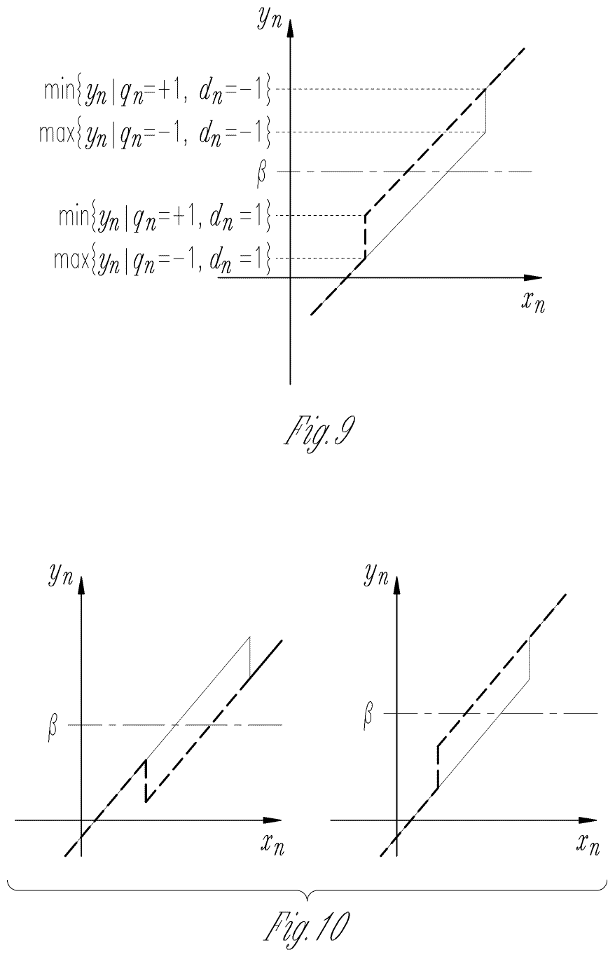

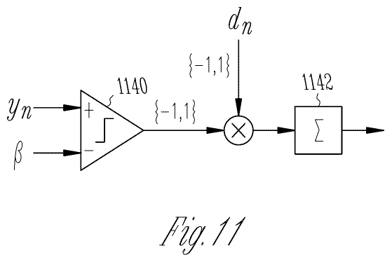

FIG. 7 is a diagram of another example of a SAR ADC 702. The ADC of FIG. 7 is the ADC of FIG. 5 modified to include a dither DAC 720. The dither DAC injects a known two-level dither sequence that takes on values +1 and −1 at the input to the ADC. The dither is subtracted out at 722 (e.g., with a lookup table) to prevent corrupting the ADC output. The effect of the dither is leveraged to expose the error canceled by calibration.

FIG. 8A is a graph showing transfer curves of node zₙ of the ADC in FIG. 7 versus the input xₙ. The graph shows a plot of the transfer curve 824 for no dither added, the transfer curve 826 for dither dₙ set to −1, and the transfer curve 828 for the dither dₙ set to +1.

FIG. 8B is a graph showing the effect on the transfer curve of yₙ versus xₙ of adding the dither sequence and then canceling the dither sequence. A transfer curve 830 for dₙ=−1 and a transfer curve 832 for dₙ=+1 are shown. The graph shows a region that is a gap at an approximate midpoint β between the transfer curves. For the ADC output yₙ, there is a higher probability that yₙ will be greater than β(yₙ>β) when the dither value dₙ=+1, and there is a higher probability that yₙ will be less than β(yₙ<β) when the dither value dₙ=−1. Thus, the dither sequence causes an imbalance in probability of the output of the ADC. Because the dither sequence is known, the effect of errors in the ADC on the imbalance allows for the error to be extracted and corrected by calibration.

The calibration process includes the following steps. The midpoint β is computed, the instantaneous error polarity is determined, and the correction coefficients or correction factors for the calibration are determined. The correction factors are used to correct for the errors e₊₁ and e⁻¹ discussed previously herein to reduce the error. The calibration process can be run in the background of the operation of the ADC and the correction factors can be recurrently updated (e.g., periodically according to a schedule).

FIG. 9 is an illustration of a graphical method of computing the midpoint β. The computation is based on the measured minimums and maximums of yₙ determined for the comparator decisions qₙ and the dither sequence values dₙ. The minimum output yₙ for qₙ=+1 and dₙ=−1 is measured, the maximum output yₙ for qₙ=−1 and dₙ=−1 is measured, the minimum yₙ for qₙ=+1 and dₙ=+1 is measured, and the maximum yₙ for qₙ=−1 and dₙ=+1 is measured. The midpoint β is the average of some or all of the measured minimums and maximums. The minimums and maximums can be determined in the digital domain from monitoring when yₙ equals a maximum or minimum over a specified period of time. Once the midpoint β is determined, the dither sequence causes an imbalance in yₙ, and yₙ will have a greater probability of being higher or lower than β depending on the value of the dither sequence dₙ. This imbalance can be detected to determine the polarity of the error.

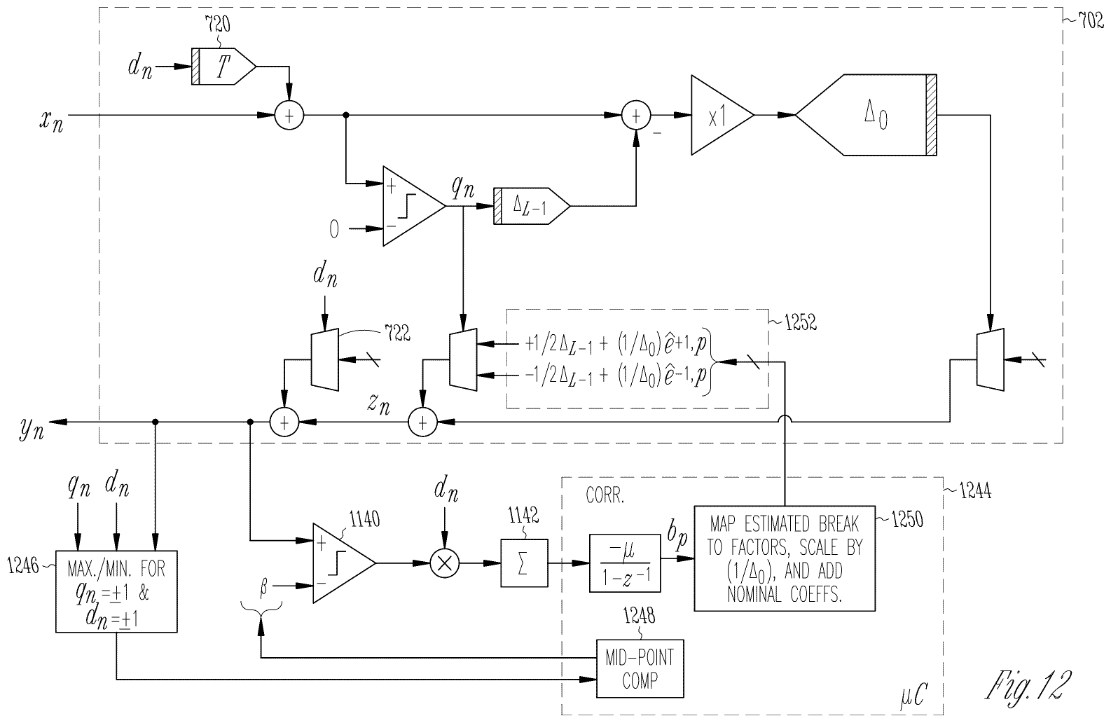

FIG. 10 shows graphs of transfer functions of yₙ versus xₙ for different error polarities. FIG. 11 is a diagram of a circuit to extract the error polarity. The circuit includes a comparator 1140 and a block accumulator 1142. The negative input to the comparator 1140 is the midpoint β and the positive input to the comparator is yₙ. The output of the block accumulator 1142 is a number that will tend to be negative or positive depending on the error polarity. The output of the block accumulator 1142 is a measure of the instantaneous error. When the midpoint β is computed and the instantaneous error is determined, the correction factors for the calibration can be updated.

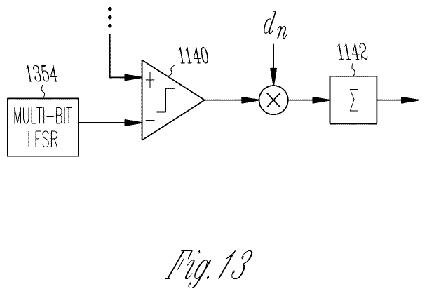

FIG. 12 is a diagram of calibration circuitry to produce correction factors to calibrate the SAR ADC 702. The calibration circuitry can include a microcontroller 1244 (μC) or other logic circuitry (e.g., a microprocessor etc.) to perform the functions described. Block 1246 identifies the maximums and minimums of yₙ for values of qₙ and dₙ and block 1248 computes the midpoint β. Blocks 1246 and 1248 may be a separate circuit from the microcontroller 1244 or may be included in the microcontroller 1244. Block accumulator 1142 provides the measured instantaneous error to the microcontroller 1244.

The instantaneous error output from the block accumulator 1142 is input to accumulator 1250. The output of accumulator 1250 goes up or down based on its input. For measurement cycle after cycle the instantaneous error gets smaller and eventually goes to zero on average. The result is the output of the accumulator 1250 converges to a break estimate bp (=e₊₁−e₋₁). The converged solution bₚ is used to map the error to correction factors (e.g., using a look up table stored in a memory of the microcontroller 1244). At block 1252, the correction factors +(1/Δ₀)e_{+1,p} and +(1/Δ₀)e_{-1,p} are used to modify the bit trial results +½Δ_{L-1} and −½Δ_{L-1}, respectively. The correction factors are recurrently updated and used to adjust results of the ADC bit trials.

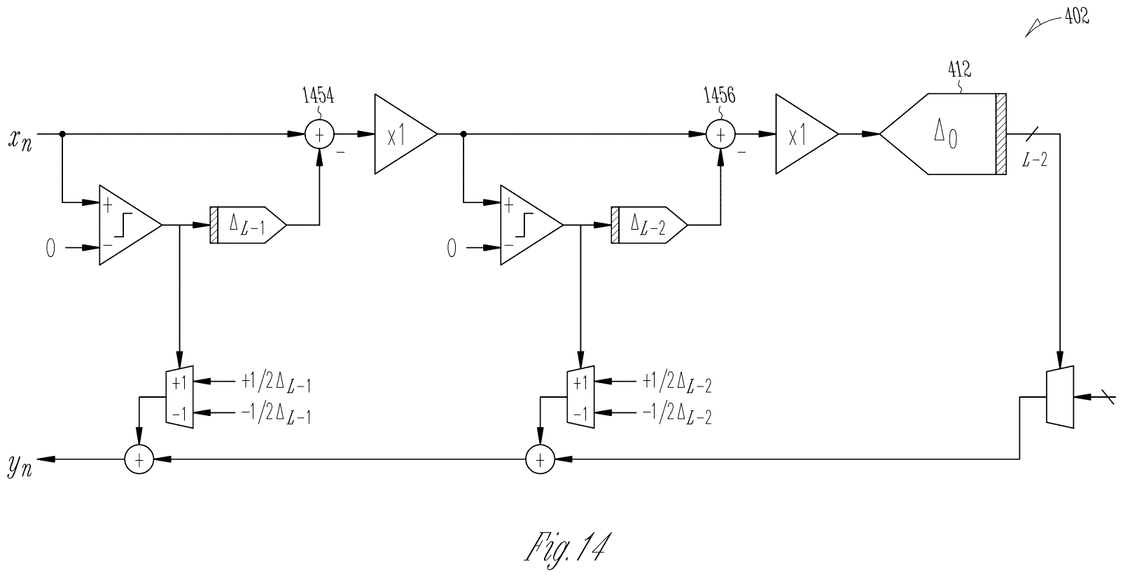

FIG. 13 is an alternative circuit used to determine the instantaneous error. The circuit uses pseudo-random noise as the midpoint β for the dithered bit trials. The Blocks 1246 and 1248 in FIG. 12 are replaced by a multi-bit linear feedback shift register (LFSR) 1354. The result is a noisy zero-mean sequence that is used for the midpoint instead of the averaging of the determined minimum and maximums of yₙ.

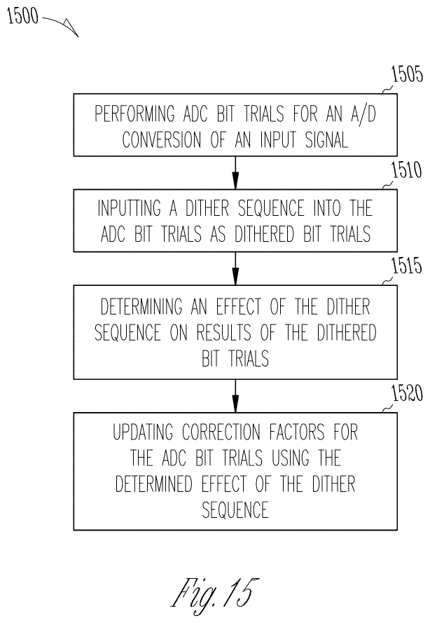

FIG. 14 is a diagram of another example of a model of a SAR ADC 402. The example of FIG. 14 is similar to the example of FIG. 4, but FIG. 14 shows the first DAC element Δ_{L-1} and the second DAC element Δ_{L-2} isolated from the rest of the system. In the first bit trail, a dither sequence is injected into summing node 1454 as described regarding FIG. 7 to calibrate the first bit trial. In the second bit trial, a dither sequence is injected into summing node 1456 to calibrate the second bit trial. A dither sequence is injected similarly for calibration of the remaining bit trials. Summing node 1454 and summing node 1456 are physically the same summing node, but they can be treated as different summing nodes from an operation point of view.

For completeness, FIG. 15 is a flow diagram of an example of a method of calibration of a SAR ADC. The method can be performed using the example ADC and calibration circuitry of FIG. 12. At block 1505, ADC bit trials for an analog-to-digital (A/D) conversion of an input signal are performed. An ADC bit trial includes comparing the input signal to a state of a weighted circuit element (e.g., a weighted DAC). At block 1510, a dither sequence is input into the ADC bit trials as dithered bit trials. At block 1515, an effect of the dither sequence on results of the dithered bit trials is determined. Another effect of the dither sequence is removed from the results of the dithered ADC bit trials. At block 1520, correction factors for calibration of the ADC are determined using the determined effect of the dither sequence on the ADC bit trials. The correction factors are used to modify ADC bit trial results to remove the effect of error in the A/D conversions by the ADC.

The techniques described herein reduce errors associated with ADCs through calibration. The techniques allow calibration to run in the background or parallel with the operation of the ADCs without interrupting normal ADC operation. The impact of the calibration on operation of the ADC is minimal and thus the techniques are suitable for high-speed designs.

### ADDITIONAL DESCRIPTION AND ASPECTS

In a first Aspect (Aspect 1) an ADC comprises bit trial circuitry configured to perform ADC bit trials that compare an input signal to states of weighted circuit elements; a dither digital-to-analog converter (DAC) to receive a dither sequence and apply a dither signal to the bit trial circuitry; and calibration circuitry. The calibration circuitry is configured to input a dither sequence into the ADC bit trials as dithered bit trials; determine an effect of the dither sequence on results of the dithered bit trials; and update correction factors used to adjust results of the ADC bit trials using the determined effect of the dither sequence.

In Aspect 2, the subject matter of Aspect 1 optionally includes calibration circuitry configured to compute a midpoint for the dithered bit trials, compare results of the dithered bit trials to the midpoint to measure instantaneous errors in the dithered bit trials, and recurrently initiate dithered bit trials to determine the updated correction factors based on the measured instantaneous errors.

In Aspect 3, the subject matter of Aspect 2 optionally includes calibration circuitry that includes a memory to store correction factors for the ADC bit trials and logic circuitry. The logic circuitry is configured to map ADC bit trial outputs to the updated correction factors and adjust results of the ADC bit trials using the updated correction factors.

In Aspect 4, the subject matter of Aspect 3 optionally includes logic circuitry that includes an accumulator configured to receive the instantaneous errors in the dithered bit trials and produce a value of convergence of the instantaneous errors in the dithered bit trials. The calibration circuitry is configured to calibrate the ADC by mapping the value of convergence of the instantaneous errors to the updated correction factors.

In Aspect 5, the subject matter of one or any combination of Aspects 2-4 optionally includes calibration circuitry with logic circuitry configured to adjust results of the ADC bit trials using the updated correction factors, and recurrently initiate the dithered bit trials to recurrently update the corrections factors toward a calibration corrections factor solution.

In Aspect 6, the subject matter of one or any combination of Aspects 2-5 optionally includes calibration circuitry configured to determine one or both of dither bit trial result maximums and minimums for a first dither sequence value, determine one or both of dither bit trial result maximums and minimums for a second dither sequence value, and compute an average of the one or both of dither bit trial result maximums and minimums determined for the first and second dither sequence values as the midpoint for the dithered bit trials.

In Aspect 7, the subject matter of one or any combination of Aspects 2-6 optionally includes calibration circuitry configured to use pseudo-random noise as the midpoint for the dithered bit trials.

In Aspect 8, the subject matter of one or any combination of Aspects 1-7 optionally includes the ADC being a multi-bit successive approximation register ADC (SAR ADC), and the calibration circuitry is configured to perform the dithered bit trials and calibrate the correction factors for the SAR ADC.

In Aspect 9, the subject matter of one or any combination of Aspects 1-8 optionally includes calibration circuitry configured to perform the dithered bit trials parallel to the ADC bit trials.

Aspect 10 includes subject matter (such as a method of calibration of an ADC) or can optionally be combined with one or any combination of Aspects 1-9 to include such subject matter, comprising performing ADC bit trials for an analog-to-digital (A/D) conversion of an input signal, wherein an ADC bit trial includes comparing the input signal to a state of a weighted circuit element, inputting a dither sequence into the ADC bit trials as dithered bit trials, determining an effect of the dither sequence on results of the dithered bit trials, and updating correction factors for the ADC bit trials using the determined effect of the dither sequence.

In Aspect 11, the subject matter of Aspect 10 optionally includes determining a midpoint for the dithered bit trials, measuring instantaneous errors in the dithered bit trials by comparing results of the dithered bit trials to the midpoint for values of the dither sequence, and determining updated correction factors based on the measured instantaneous errors in the dithered bit trials.

In Aspect 12, the subject matter of Aspect 11 optionally includes mapping ADC bit trial outputs to the updated correction factors.

In Aspect 13, the subject matter of Aspect 12 optionally includes determining a value of convergence of the instantaneous errors in the dithered bit trials by accumulating the instantaneous errors in the dithered bit trials and calibrating the ADC by mapping the value of convergence of the instantaneous errors to the updated correction factors.

In Aspect 14, the subject matter of one or any combination of Aspects 11-13 optionally includes adjusting results of the ADC bit trials using the updated correction factors, and repeating the dithered bit trials and reducing the determined error in the ADC bit trials by updating the correction factors.

In Aspect 15, the subject matter of one or any combination of Aspects 11-14 optionally includes determining one or both of bit trial result maximums and minimums for a first dither sequence value, determining one or both of bit trial result maximums and minimums for a second dither sequence value, and averaging the determined one or both of bit trial result maximums and minimums for the first and second dither sequence values.

In Aspect 16, the subject matter of one or any combination of Aspects 11-15 optionally includes using pseudo-random noise as the midpoint for the dithered bit trials.

In Aspect 17, the subject matter of one or any combination of Aspects 11-16 optionally includes performing the dithered bit trials parallel to the ADC bit trials.

Aspect 18 includes subject matter (or can optionally be combined with one or any combination of Aspects 1-17 to include such subject matter) such as a computer readable storage medium including instructions, that when performed using a controller for calibration circuitry of an analog-to-digital converter (ADC) cause the calibration circuitry to perform acts comprising initiating dithered bit trials of the ADC, wherein a dithered bit trial inputs a dither sequence into ADC bit trials that include comparing an input signal to a state of a weighted circuit element of the ADC; determining a midpoint for the dithered bit trials; determining instantaneous errors in the dithered bit trials by comparing results of the dithered bit trials to the midpoint for values of the dither sequence; determining an error in the ADC bit trials using a determined convergence of the instantaneous errors in the dithered bit trials; removing an effect of the dither sequence from results of the dithered bit trials; and updating correction factors for the ADC bit trials according to the determined error in the ADC bit trials.

In Aspect 19, the subject matter of Aspect 18 optionally further includes instructions that cause the calibration circuitry to determine bit trial result maximums and minimums for a first dither sequence value, determine bit trial result maximums and minimums for a second dither sequence value, and average the determined bit trial result maximums and minimums for the first and second dither sequence values as the midpoint for the dithered bit trials.

In Aspect 20, the subject matter of one or both of Aspects 18 and 19 optionally further includes instructions that cause the calibration circuitry to determine a value of convergence of the instantaneous errors in the dithered bit trials by accumulating the instantaneous errors in the dithered bit trials; and map the value of convergence of the instantaneous errors to updated correction factors.

These non-limiting Aspects can be combined in any permutation or combination. The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. Method examples described herein can be machine or computer-implemented at least in part.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. An analog-to-digital converter (ADC) comprising:
bit trial circuitry configured to perform ADC bit trials that compare an input signal to states of weighted circuit elements;
a dither digital-to-analog converter (DAC) to receive a dither sequence and apply a dither signal to the bit trial circuitry; and
calibration circuitry configured to:
input a dither sequence into the ADC bit trials as dithered bit trials;
determine an effect of the dither sequence on results of the dithered bit trials; and
update correction factors used to adjust results of the ADC bit trials using the determined effect of the dither sequence.

2. The ADC of claim 1,
wherein the calibration circuitry is configured to:
compute a midpoint for the dithered bit trials;
compare results of the dithered bit trials to the midpoint to measure instantaneous errors in the dithered bit trials; and
recurrently initiate dithered bit trials to determine the updated correction factors based on the measured instantaneous errors.

3. The ADC of claim 2, wherein the calibration circuitry includes:
a memory to store correction factors for the ADC bit trials; and
logic circuitry configured to:
map ADC bit trial outputs to the updated correction factors; and
adjust results of the ADC bit trials using the updated correction factors.

4. The ADC of claim 3,
wherein the logic circuitry includes an accumulator configured to receive the instantaneous errors in the dithered bit trials and produce a value of convergence of the instantaneous errors in the dithered bit trials; and
wherein the calibration circuitry is configured to calibrate the ADC by mapping the value of convergence of the instantaneous errors to the updated correction factors.

5. The ADC of claim 2, wherein the calibration circuitry includes logic circuitry configured to:
adjust results of the ADC bit trials using the updated correction factors; and
recurrently initiate the dithered bit trials to recurrently update the corrections factors toward a calibration corrections factor solution.

6. The ADC of claim 2, wherein the calibration circuitry is configured to:
determine one or both of dither bit trial result maximums and minimums for a first dither sequence value;
determine one or both of dither bit trial result maximums and minimums for a second dither sequence value; and
compute an average of the one or both of dither bit trial result maximums and minimums determined for the first and second dither sequence values as the midpoint for the dithered bit trials.

7. The ADC of claim 2, wherein the calibration circuitry is configured to use pseudo-random noise as the midpoint for the dithered bit trials.

8. The ADC of claim 1, wherein the ADC is a multi-bit successive approximation register ADC (SAR ADC), and the calibration circuitry is configured to perform the dithered bit trials and calibrate the correction factors for the SAR ADC.

9. The ADC of claim 1, wherein the calibration circuitry is configured to perform the dithered bit trials parallel to the ADC bit trials.

10. A method of calibration of an analog-to-digital converter (ADC), the method comprising:
performing ADC bit trials for an analog-to-digital (A/D) conversion of an input signal, wherein an ADC bit trial includes comparing the input signal to a state of a weighted circuit element;
inputting a dither sequence into the ADC bit trials as dithered bit trials;
determining an effect of the dither sequence on results of the dithered bit trials; and
updating correction factors for the ADC bit trials using the determined effect of the dither sequence.

11. The method of claim 10, wherein the determining the effect of the dither sequence includes:
determining a midpoint for the dithered bit trials;
measuring instantaneous errors in the dithered bit trials by comparing results of the dithered bit trials to the midpoint for values of the dither sequence; and
determining updated correction factors based on the measured instantaneous errors in the dithered bit trials.

12. The method of claim 11, wherein the updating the correction factors includes:
mapping ADC bit trial outputs to the updated correction factors.

13. The method of claim 12, including:
determining a value of convergence of the instantaneous errors in the dithered bit trials by accumulating the instantaneous errors in the dithered bit trials; and
calibrating the ADC by mapping the value of convergence of the instantaneous errors to the updated correction factors.

14. The method of claim 11, including:
adjusting results of the ADC bit trials using the updated correction factors; and
repeating the dithered bit trials and reducing the determined error in the ADC bit trials by updating the correction factors.

15. The method of claim 11, wherein the determining the midpoint for the dithered bit trials includes:
determining one or both of bit trial result maximums and minimums for a first dither sequence value;
determining one or both of bit trial result maximums and minimums for a second dither sequence value; and
averaging the determined one or both of bit trial result maximums and minimums for the first and second dither sequence values.

16. The method of claim 11, wherein the determining the midpoint for the dithered bit trials includes using pseudo-random noise as the midpoint for the dithered bit trials.

17. The method of claim 10, including performing the dithered bit trials parallel to the ADC bit trials.

18. A non-transitory computer readable storage medium including instructions, that when performed using a controller for calibration circuitry of an analog-to-digital converter (ADC) cause the calibration circuitry to perform acts comprising:
initiating dithered bit trials of the ADC, wherein a dithered bit trial inputs a dither sequence into ADC bit trials that include comparing an input signal to a state of a weighted circuit element of the ADC;
determining a midpoint for the dithered bit trials;
determining instantaneous errors in the dithered bit trials by comparing results of the dithered bit trials to the midpoint for values of the dither sequence;
determining an error in the ADC bit trials using a determined convergence of the instantaneous errors in the dithered bit trials; and
updating correction factors for the ADC bit trials according to the determined error in the ADC bit trials.

19. The non-transitory computer readable storage medium of claim 18, further including instructions that when performed by the controller, cause the calibration circuitry to perform acts including:
determining bit trial result maximums and minimums for a first dither sequence value;
determining bit trial result maximums and minimums for a second dither sequence value; and
averaging the determined bit trial result maximums and minimums for the first and second dither sequence values as the midpoint for the dithered bit trials.

20. The non-transitory computer readable storage medium of claim 18, further including instructions that when performed by the controller, cause the calibration circuitry to perform acts including:
determining a value of convergence of the instantaneous errors in the dithered bit trials by accumulating the instantaneous errors in the dithered bit trials; and
mapping the value of convergence of the instantaneous errors to updated correction factors.
